(19) United States
(12) Patent Application Publication
(10) Pub. No.: US 2026/0324139 A1
(43) Pub. Date: Oct. 15, 2026

(54) LIGHT-EMITTING DIODE PANEL

(71) Applicant: Wuhan China Star Optoelectronics Semiconductor Display Technology Co., Ltd., Wuhan, Hubei (CN)

(72) Inventors: Shilei KAN, Wuhan, Hubei (CN); Sheng CHEN, Wuhan, Hubei (CN); Liang SUN, Wuhan, Hubei (CN)

(21) Appl. No.: 18/995,915

(22) PCT Filed: Aug. 12, 2024
(86) PCT No.: PCT/CN2024/111334

§ 371 Date: Jan. 17, 2025

(30) Foreign Application Priority Data
Nov. 29, 2023 (CN) 202311626225.3

(51) Int. Cl. H10H 20/831; H10H 20/819

(52) U.S. Cl. CPC H10H 20/8312; H10H 20/819

(57) ABSTRACT

A light-emitting diode (LED) panel is provided. The LED panel features a second conductive layer that covers the first conductive layer in an area corresponding to trenches to increase a thickness of the first conductive layer in the area of the trenches.

The present application claims priority to Chinese Patent Application No. 202311626225.3, filed on Nov. 29, 2023, the contents of which are incorporated herein by reference in their entirety.

### FIELD OF DISCLOSURE

The present application relates to a field of display technology, specifically to a light-emitting diode (LED) panel.

### DESCRIPTION OF RELATED ART

With the popularity of augmented reality (AR) and virtual reality (VR) technologies, micro-display technologies featuring high brightness and high pixel density (PPI) have become the preferred display solutions. Silicon-based micro-LED display technology has emerged as the most competitive solution, differing from traditional LED manufacturing processes. The production of silicon-based micro-LEDs is more complex, involving the integration of a driving substrate with the LED epitaxy followed by the patterning and connection of the LED epitaxy to the driving substrate. During the integration of the LED epitaxy with the driving substrate, bonding metals are introduced. Both the LED epitaxy and the bonding metals are relatively thick, and the etching and patterning between micro-LED pixels can create significant step differences in the trenches. When a conductive film is subsequently deposited, it can thin out or even break at these step differences between the micro-LED pixels, affecting the performance of the silicon-based micro-LEDs.

### SUMMARY OF INVENTION

The embodiments of the present application provide a light-emitting diode (LED) panel that enhances the stability of LED devices.

According to one embodiment of the present application, a light-emitting diode (LED) panel is provided, including:
a driving substrate, wherein the driving substrate includes a base substrate and a first conductive bonding layer disposed on the base substrate;
a second conductive bonding layer, wherein the second conductive bonding layer is bonded to one side of the first conductive bonding layer away from the base substrate;
an LED epitaxial layer, wherein the LED epitaxial layer comprises a plurality of LEDs, the LEDs are disposed on one side of the second conductive bonding layer away from the base substrate, one end of each of the LEDs is electrically connected to the second conductive bonding layer, and a trench is defined between each two adjacent LEDs, the trenches extending through the LED epitaxial layer, the second conductive bonding layer, and the first conductive bonding layer;
a protective layer, wherein the protective layer covers the LED epitaxial layer and the trenches, the protective layer comprising a plurality of openings that expose the LEDs;
a first conductive layer, wherein the first conductive layer covers the protective layer and is connected to another end of the LEDs through the openings, and a portion of the first conductive layer covers an area of the trenches; and
a second conductive layer, wherein the second conductive layer is directly disposed on one side of the first conductive layer away from the base substrate, and the second conductive layer at least covers the area of the trenches.

### BRIEF DESCRIPTION OF DRAWINGS

FIG. 1 is a schematic structural view of a light-emitting diode (LED) panel according to one embodiment of the present application;

FIG. 2 is an enlarged view of part A of FIG. 1;

FIG. 3 is an enlarged view of another structure of part A in FIG. 1;

FIG. 4 is a schematic view illustrating step S1 of a manufacturing method for the LED panel according to one embodiment of the present application;

FIG. 5 is a schematic view illustrating step S2 of the manufacturing method for the LED panel according to one embodiment of the present application;

FIG. 6 is a schematic view illustrating step S3 of the manufacturing method for the LED panel according to one embodiment of the present application;

FIG. 7 is a schematic view illustrating step S4 of the manufacturing method for the LED panel according to one embodiment of the present application;

FIG. 8 is a schematic view of another structure of the LED panel provided in one embodiment of the present application;

FIG. 9 is an enlarged view of part A in FIG. 8.

### DETAILED DESCRIPTION OF EMBODIMENTS

In the following, a clear and complete description of the technical solutions in the embodiments of this application is given in conjunction with the accompanying drawings. It is evident that the embodiments described herein represent only a portion of the embodiments of this application and not all embodiments. All other embodiments obtained by those skilled in the art based on the embodiments in this application, without the need for creative labor, fall within the scope of protection of this application. Furthermore, it should be understood that the specific embodiments described here are intended only to explain and illustrate this application and are not intended to limit this application. In this application, unless otherwise specified, directional terms such as “above” and “below” generally refer to the direction above and below in the actual use or working state of the device, specifically the direction shown in the drawings; “inner” and “outer” refer to the contours of the device; terms like “first,” “second,” “third,” etc., are used merely as labels and do not impose numerical requirements or establish a sequence.

The embodiments of the application provide a light-emitting diode (LED) panel, which is detailed below. It should be noted that the sequence of descriptions of the following embodiments does not limit the preferred sequence of the embodiments.

One embodiment of the present application provides a light-emitting diode (LED) panel, including:
a driving substrate, wherein the driving substrate includes a base substrate and a first conductive bonding layer disposed on the base substrate;
a second conductive bonding layer, wherein the second conductive bonding layer is bonded to one side of the first conductive bonding layer away from the base substrate;
an LED epitaxial layer, wherein the LED epitaxial layer includes a plurality of LEDs, the LEDs are disposed on one side of the second conductive bonding layer away from the base substrate, one end of each LED is electrically connected to the second conductive bonding layer, and a trench is provided between each two adjacent LEDs, the trenches extending through the LED epitaxial layer, the second conductive bonding layer, and the first conductive bonding layer;
a protective layer, wherein the protective layer covers the LED epitaxial layer and the trenches, the protective layer including a plurality of openings that expose the LEDs;
a first conductive layer, wherein the first conductive layer covers the protective layer and is connected to another end of the LEDs through the openings, and a portion of the first conductive layer covers an area of the trenches;
a second conductive layer, wherein the second conductive layer is directly disposed on one side of the first conductive layer away from the base substrate, and the second conductive layer at least covers the area of the trenches.

Optionally, in some embodiments of the present application, the first conductive layer includes a first portion and a second portion connected to the first portion; the first portion is disposed in an area of the LEDs, and the second portion is disposed in the area of the trenches; a thickness of the first portion is greater than a thickness of the second portion;
a combined thickness of the second portion and the second conductive layer is greater than or equal to the thickness of the first portion.

Optionally, in some embodiments of the present application, each of the trenches comprises a first trench and a second trench connected to each other; each of the first trenches extends through the LED epitaxial layer, and each of the second trenches extends through the second conductive bonding layer and the first conductive bonding layer;
a width of an opening end of the first trench is greater than a width of an opening end of the second trench; a thickness of a portion of the first conductive layer located at the first trench is greater than a thickness of a portion of the first conductive layer located at the second trench; a thickness of a portion of the second conductive layer located at the first trench is greater than a thickness of a portion of the second conductive layer located at the second trench;
a combined thickness of the portion of the first conductive layer and the portion of the second conductive layer located at the second trench is greater than or equal to the thickness of the first portion.

Optionally, in some embodiments of the present application, the second conductive layer includes a covering portion and a filling portion connected to the covering portion; the covering portion covers an area of the second portion corresponding to the first trench, and the filling portion fills a recess of the second portion corresponding to the second trench.

Optionally, in some embodiments of the present application, the second conductive layer covers a surface of the second portion away from the base substrate.

Optionally, in some embodiments of the present application, the LED panel further includes a third conductive layer, wherein the third conductive layer is disposed between the LEDs and the second conductive bonding layer, and the second trench extends through the third conductive layer.

Optionally, in some embodiments of the present application, a width of an opening end of each of the trenches is less than 0.6 micrometers.

Optionally, in some embodiments of the present application, a material of the second conductive layer is selected from at least one of metals or metal oxides.

Optionally, in some embodiments of the present application, the second conductive layer is a single-layer structure.

Optionally, in some embodiments of the present application, wherein the second conductive layer is a multi-layer stack structure.

Optionally, in some embodiments of the present application, the second conductive layer includes an electroplating seed layer and an electroplated metal layer disposed on the electroplating seed layer, with the electroplating seed layer covering the first conductive layer.

In the embodiments of this application, the light-emitting diode (LED) panel features a second conductive layer that covers the first conductive layer in the area corresponding to the trenches. This arrangement thickens the first conductive layer the area of the trenches, mitigating the risk of the first conductive layer becoming thin, breaking, or forming poor electrical contact at the trenches. Consequently, this improves the connectivity and electrical stability of the first conductive layer between the LEDs, thereby enhancing the performance and manufacturing yield of the LED panel.

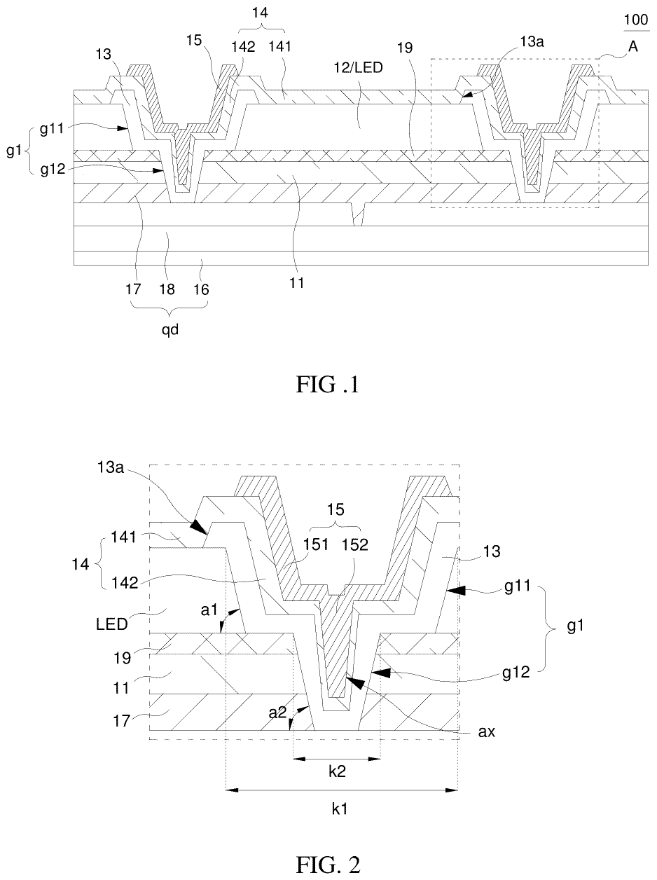

Please refer to FIGS. 1 and 2. The embodiment of this application provides a light-emitting diode (LED) panel 100, which includes a driving substrate qd, a second conductive bonding layer 11, an LED epitaxial layer 12, a protective layer 13, a first conductive layer 14, and a second conductive layer 15.

The driving substrate qd includes a base substrate 16 and a first conductive bonding layer 17 disposed on the base substrate 16. The second conductive bonding layer 11 is bonded to one side of the first conductive bonding layer 17 that is away from the base substrate 16.

The LED epitaxial layer 12 includes a plurality of LEDs. The LEDs are set on one side of the second conductive bonding layer 11 that is away from the base substrate 16. One end of each LED is electrically connected to the second conductive bonding layer 11. Trenches g1 are established between adjacent LEDs, and the trenches g1 extend through the LED epitaxial layer 12, the second conductive bonding layer 11, and the first conductive bonding layer 17.

The protective layer 13 covers the LED epitaxial layer 12 and the trenches g1. A plurality of openings 13a are set on the protective layer 13, exposing the LEDs.

The first conductive layer 14 covers the protective layer 13 and connects to the other end of each LED through the corresponding opening 13a. Part of the first conductive layer 14 covers an area of the trenches g1. The second conductive layer 15 is directly disposed on one side of the first conductive layer 14 that is away from the base substrate 16 and covers at least the area of the trenches g1.

In the embodiments of this application, the LED panel 100 includes the second conductive layer 15 covering the first conductive layer 14 in the area corresponding to the trenches g1 to increase a thickness of the first conductive layer 14 in the area of the trenches g1. This compensates for the risk of thinning, breaking, or poor connection of the first conductive layer 14 at the trenches g1, thereby improving the connectivity and electrical stability of the first conductive layer 14 between the LEDs, and enhancing the performance and manufacturing yield of the LED panel 100.

Optionally, a width of an opening end of the trench g1 is less than 0.6 micrometers, which can be, for example, 0.59 micrometers, 0.55 micrometers, 0.5 micrometers, 0.4 micrometers, 0.3 micrometers, 0.2 micrometers, or 0.1 micrometers.

Due to the addition of the second conductive layer 15, the electrical continuity and stability between the LEDs are enhanced, allowing for the reduction of the width of the opening end of the trench g1, which improves the resolution of the LED panel 100.

It should be noted that the width of the opening end of the trench g1 is referred to as a width k1 of a first trench g11 in the text below.

Optionally, the driving substrate qd also includes a thin-film transistor structure layer 18. The thin-film transistor structure layer 18 is disposed between the base substrate 16 and the first conductive bonding layer 17. The first conductive bonding layer 17 is electrically connected to thin-film transistors in the thin-film transistor structure layer 18.

Optionally, the first conductive layer 14 includes a first portion 141 and a second portion 142 connected to the first portion 141. The first portion 141 is located in an area of the LEDs. The second portion 142 is located in the area of trenches g1. A thickness of the first portion 141 is greater than a thickness of the second portion 142.

In the area of the trenches g1, a combined thickness of the second portion 142 and the second conductive layer 15 is greater than or equal to the thickness of the first portion 141.

In this embodiment, by setting the total thickness of the conductive stack (the second portion 142+the second conductive layer 15) in the area of the trench g1 to be greater than or equal to the thickness of the first portion 141, the risk of fractures or poor connections in the conductive layer at the trench is reduced, and it also lowers the overall impedance of the first conductive layer 14.

It is important to understand that the thickness of the second portion 142 represents an average thickness of the second portion 142, the thickness of the second conductive layer 15 represents an average thickness of the second conductive layer 15, and the thickness of the first portion 141 represents an average thickness of the first portion 141.

In some embodiments, the thickness of the second portion 142 is the minimum thickness of the second portion 142, the thickness of the second conductive layer 15 is the minimum thickness of the second conductive layer 15, and the thickness of the first portion 141 is the maximum or average thickness of the first portion 141. This further enhances the stability of the conductive connection in the area of the trench g1 and reduces impedance.

In this setup, the LEDs are connected to the first conductive layer 14. The resistivity of the second conductive layer 15 is lower than the resistivity of the first conductive layer 14, which improves the electrical conductivity between the connected LEDs and can also reduce the impedance of the first conductive layer 14.

Optionally, the material of the first conductive layer 14 is a transparent conductive material, such as indium tin oxide (ITO) or indium zinc oxide (IZO) and other oxides.

The material for the second conductive layer 15 can be selected from at least one of metals or metal oxides. For example, it could use metals such as chromium, copper, aluminum, gold, platinum, silver, zinc, molybdenum, tantalum, titanium, tungsten, manganese, nickel, iron, cobalt, or alloys containing any of these metals, or metal oxides such as indium tin oxide or indium zinc oxide combined with any of these metal elements.

Optionally, the second conductive layer 15 can be a single-layer structure or a multi-layer stack structure.

Optionally, the LED includes a light-emitting layer and a first electrode and a second electrode located on opposite sides of the light-emitting layer, where the first electrode is at one end of the LED and the second electrode is at the other end of the LED.

Optionally, the trench g1 comprises a first trench g11 and a second trench g12 interconnected. The first trench g11 extends through the LED epitaxial layer 12. The second trench g12 extends through both the second conductive bonding layer 11 and the first conductive bonding layer 17.

A width k1 of an opening end of the first trench g11 is greater than a width k2 of an opening end of the second trench g12. A thickness of a portion of the first conductive layer 14 located in the first trench g11 is greater than a thickness of a portion of the first conductive layer 14 located in the second trench g12. Similarly, a thickness of a portion of the second conductive layer 15 located in the first trench g11 is greater than a thickness of a portion of the second conductive layer 15 at the part located in the second trench g12.

The combined thickness of the first conductive layer 14 and the second conductive layer 15, where both are located in the second trench g12, is greater than or equal to the thickness of the first portion 141 of the first conductive layer.

It is important to understand that the second trench g12 is located in the deepest part of the trench g1. Consequently, compared to the area of the first trench g11, the sections of the second portion 142 of the first conductive layer 14 and the second conductive layer 15 located in the second trench g12 are thinner. Therefore, the second portion 142 in the area of the second trench g12 is more prone to fractures or poor connections.

Thus, setting the thickness of the conductive stack located in the area of the second trench g12 to be greater than or equal to the thickness of the first portion 141 of the first conductive layer 14 provides a more precise compensation for the thinner areas of the second portion 142, enhancing the connectivity and stability of the electrical connection.

Additionally, it can be understood that since both the first conductive layer 14 and the second conductive layer 15 are formed using deposition processes, and since the first trench g11 is located in an upper region of the trench g1, the thickness of the conductive stack in the area of the first trench g11 is greater than the thickness of the conductive stack in the area of the second trench g12.

Thus, the thickness of the conductive stack in the area of the first trench g11 is greater than the thickness of the first portion 141 of the first conductive layer 14, which further enhances the electrical connectivity and stability, as well as reduces impedance.

Optionally, the LED panel 100 can also include a third conductive layer 19, which is positioned between the LEDs and the second conductive bonding layer 11, with the second trench g12 penetrating through the third conductive layer 19.

Optionally, a slope angle al of a wall of the first trench g11 is less than a slope angle a2 of a wall of the second trench g12, and the width of the opening end k2 of the second trench g12 is smaller than the width of the opening end k1 of the first trench g11. This configuration results in a relatively smaller volume of the second trench g12, making it easier for the second conductive layer 15 to fully fill the area of the second trench g12, thereby further enhancing the continuity and stability of the conductive connections in the area of the trench g1.

Optionally, the second conductive layer 15 includes a covering portion 151 and a filling portion 152 connected to the covering portion 151, where the covering portion 151 covers the area of the second portion 142 corresponding to the first trench g11. The filling portion 152 fills a recess ax in the second portion 142 corresponding to the second trench g12.

The filling portion 152 fills the recess ax corresponding to the second trench g12, not only ensuring the electrical stability and continuity of the conductive stack in the area of the second trench g12 to the greatest extent but also reducing the path of electrical current by avoiding the electrical current's passing through a bottom area of the recess ax, thus enhancing the electrical performance.

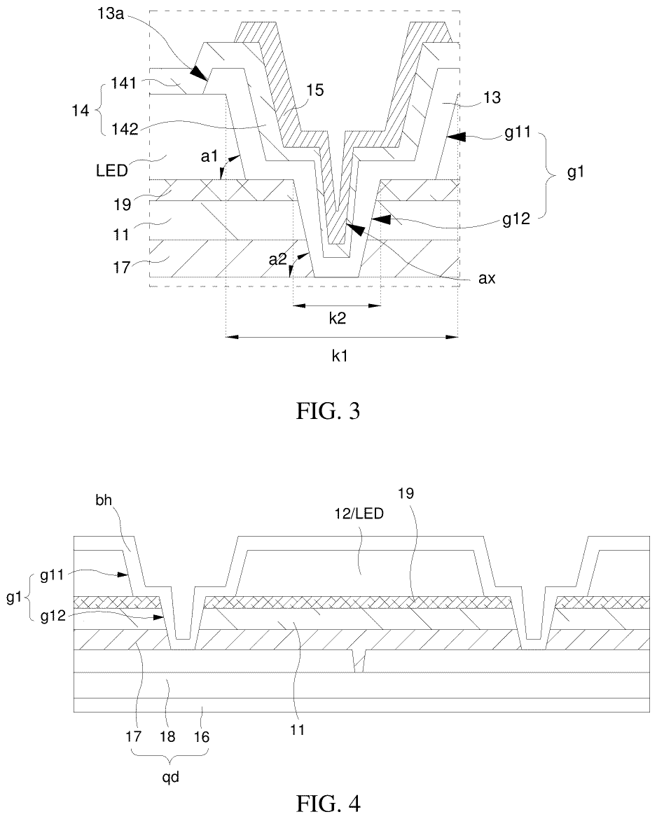

Optionally, in some embodiments as shown in FIG. 3, the second conductive layer 15 covers a surface of the second portion 142 that is away from the base substrate 16.

A manufacturing method for the LED panel 100 in one embodiment of the present application includes the following steps:

Step S1: Refer to FIG. 4, patterning the LED epitaxial material layer, the first conductive bonding material layer of the driving substrate qd, the second conductive bonding material layer, and the third conductive material layer to form the second conductive bonding layer 11, the LED epitaxial layer 12, the first conductive bonding layer 17, and the trench g1. Subsequently, form a protective material layer bh on the driving substrate qd that covers the second conductive bonding layer 11, the LED epitaxial layer 12, the first conductive bonding layer 17, and the trench g1.

Optionally, the base substrate 16 of the driving substrate qd can be a silicon-based substrate or a glass substrate, etc. A material for the first conductive bonding layer 17 and a material for the second conductive bonding layer 11 can each be at least one of Cr, Ti, Pt, Sn, Au, and Cu, or any suitable combination of these metal elements.

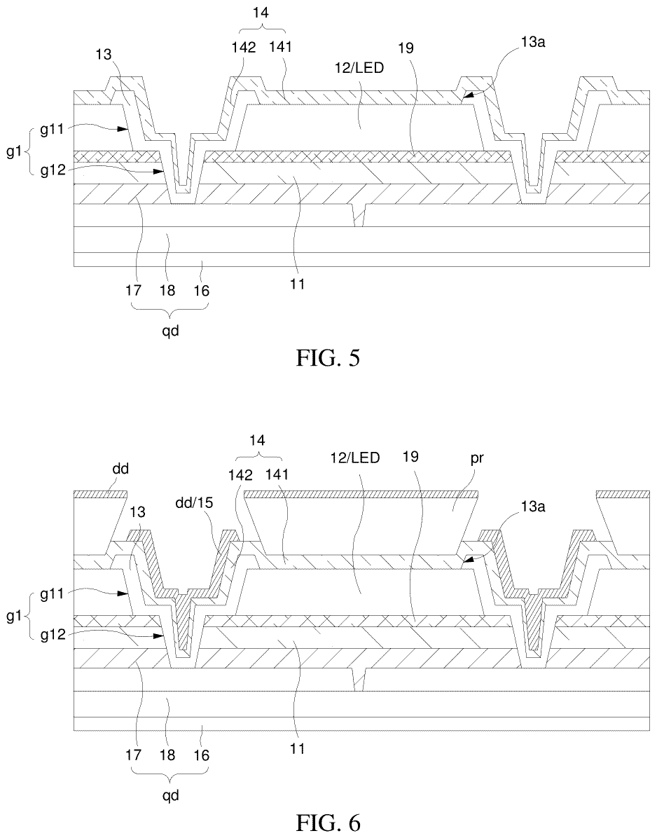

Step S2: Refer to FIG. 5, pattern the protective material layer bh to form the protective layer 13 and the openings 13a, with the openings 13a exposing the LEDs. Subsequently, form the first conductive layer 14 on the protective layer 13. The first conductive layer 14 connects to the LEDs and extends to cover the area of the trench g1.

Step S3: Refer to FIG. 6, form a patterned photoresist layer pr on the first conductive layer 14, where the photoresist layer pr is positioned over the area of the LEDs; then form a conductive material layer dd on the photoresist layer pr, with the conductive material layer dd breaking at edges of the photoresist layer pr to form the second conductive layer 15 that covers the area of the trench g1.

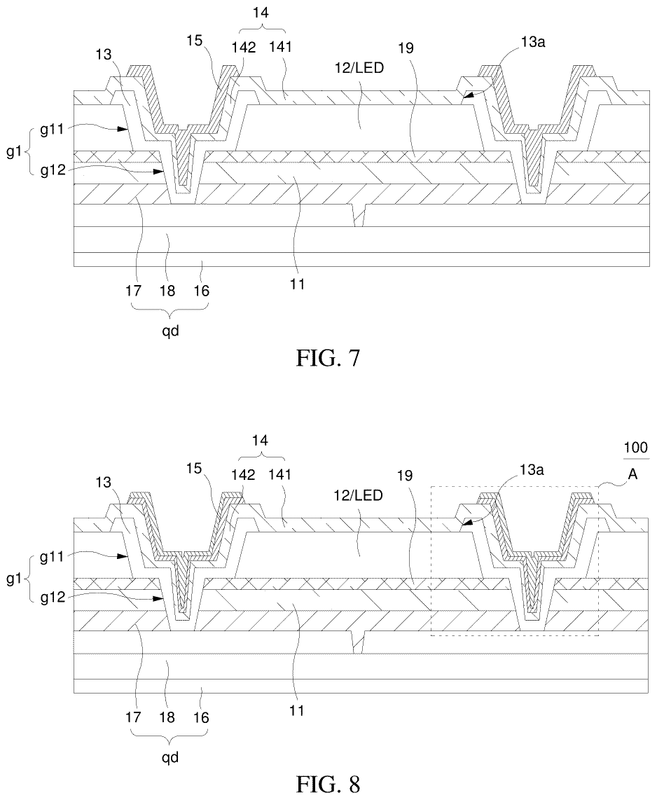

Step S4: Refer to FIG. 7, remove the photoresist layer pr and the conductive material layer dd located on the photoresist layer pr.

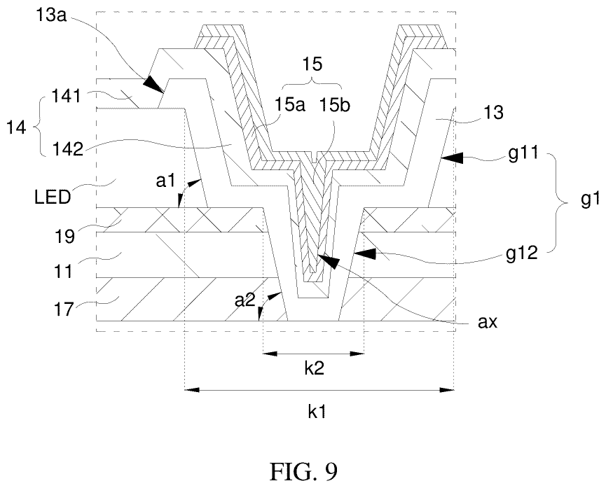

Optionally, in some embodiments as shown in FIGS. 8 and 9, which differ from the embodiment corresponding to FIG. 1, the second conductive layer 15 includes an electroplating seed layer 15a and an electroplated metal layer 15b that is disposed on the electroplating seed layer 15a. The electroplating seed layer 15a covers the first conductive layer 14.

The electroplated metal layer 15b fills the recess ax in the electroplating seed layer 15a located in the area of the second trench g12.

Compared to the chemical vapor deposition process, the use of electroplating to form the second conductive layer 15 results in a more uniform thickness, enhancing the uniformity of the thickness of the conductive stack in the area of the trench g1 and thus improving the continuity and stability of the conductive performance of the stack.

It should be noted that the structure of the LED panel 100 in this embodiment is similar or identical to the structure depicted in FIG. 1.

In the embodiments of this application, the LED panel is designed such that the second conductive layer covers the first conductive layer in the area corresponding to the trenches, thereby increasing the thickness of the first conductive layer in the area of the trenches. This compensates for the risk of thinning, cracking, or poor connection of the first conductive layer at the trenches, thereby improving the connectivity and electrical stability of the first conductive layer between the LEDs, and enhancing the performance and manufacturing yield of the LED panel.

The detailed description provided above of an LED panel in this embodiment illustrates the principles and embodiments of the application through specific examples. The description of these embodiments is intended to assist in understanding the methods of the application and its core ideas; it should not be construed as limiting the application. Additionally, it should be understood that those skilled in the art may make modifications in the specific implementations and applications based on the concepts of this application, and therefore, this specification should not be construed as limiting the scope of the application.

1. A light-emitting diode (LED) panel, comprising:
a driving substrate, wherein the driving substrate comprises a base substrate and a first conductive bonding layer disposed on the base substrate;
a second conductive bonding layer, wherein the second conductive bonding layer is bonded to one side of the first conductive bonding layer away from the base substrate;
an LED epitaxial layer, wherein the LED epitaxial layer comprises a plurality of LEDs, the LEDs are disposed on one side of the second conductive bonding layer away from the base substrate, one end of each of the LEDs is electrically connected to the second conductive bonding layer, and a trench is defined between each two adjacent LEDs, the trenches extending through the LED epitaxial layer, the second conductive bonding layer, and the first conductive bonding layer;
a protective layer, wherein the protective layer covers the LED epitaxial layer and the trenches, the protective layer comprising a plurality of openings that expose the LEDs;
a first conductive layer, wherein the first conductive layer covers the protective layer and is connected to another end of the LEDs through the openings, and a portion of the first conductive layer covers an area of the trenches; and
a second conductive layer, wherein the second conductive layer is directly disposed on one side of the first conductive layer away from the base substrate, and the second conductive layer at least covers the area of the trenches.

2. The light-emitting diode (LED) panel according to claim 1, wherein the first conductive layer includes a first portion and a second portion connected to the first portion; the first portion is disposed in an area of the LEDs, and the second portion is disposed in the area of the trenches; a thickness of the first portion is greater than a thickness of the second portion;
in the area of the trenches, a combined thickness of the second portion and the second conductive layer is greater than or equal to the thickness of the first portion.

3. The light-emitting diode (LED) panel according to claim 2, wherein the trenches comprise a first trench and a second trench connected to each other; the first trench extends through the LED epitaxial layer, and the second trench extends through the second conductive bonding layer and the first conductive bonding layer;
a width of an opening end of the first trench is greater than a width of an opening end of the second trench; a thickness of a portion of the first conductive layer located at the first trench is greater than a thickness of a portion of the first conductive layer located at the second trench; a thickness of a portion of the second conductive layer located at the first trench is greater than a thickness of a portion of the second conductive layer located at the second trench;
a combined thickness of the portion of the first conductive layer and the portion of the second conductive layer located at the second trench is greater than or equal to the thickness of the first portion.

4. The light-emitting diode (LED) panel according to claim 3, wherein the second conductive layer comprises a covering portion and a filling portion connected to the covering portion; the covering portion covers an area of the second portion corresponding to the first trench, and the filling portion fills a recess of the second portion corresponding to the second trench.

5. The light-emitting diode (LED) panel according to claim 3, wherein the second conductive layer covers a surface of the second portion away from the base substrate.

6. The light-emitting diode (LED) panel according to claim 3, further comprising a third conductive layer, wherein the third conductive layer is disposed between the LEDs and the second conductive bonding layer, and the second trench extends through the third conductive layer.

7. The light-emitting diode (LED) panel according to claim 1, wherein a width of an opening end of each of the trenches is less than 0.6 micrometers.

8. The light-emitting diode (LED) panel according to claim 1 wherein the second conductive layer is a single-layer structure.

9. The light-emitting diode (LED) panel according to claim 1 wherein the second conductive layer is a multi-layer stack structure.

10. The light-emitting diode (LED) panel according to claim 9, wherein the second conductive layer comprises an electroplating seed layer and an electroplated metal layer disposed on the electroplating seed layer, with the electroplating seed layer covering the first conductive layer.

11. A light-emitting diode (LED) panel, comprising:
a driving substrate, wherein the driving substrate comprises a base substrate and a first conductive bonding layer disposed on the base substrate;
a second conductive bonding layer, wherein the second conductive bonding layer is bonded to one side of the first conductive bonding layer away from the base substrate;
an LED epitaxial layer, wherein the LED epitaxial layer comprises a plurality of LEDs, the LEDs are disposed on one side of the second conductive bonding layer away from the base substrate, one end of each of the LEDs is electrically connected to the second conductive bonding layer, and a trench is defined between each two adjacent LEDs, the trenches extending through the LED epitaxial layer, the second conductive bonding layer, and the first conductive bonding layer;
a protective layer, wherein the protective layer covers the LED epitaxial layer and the trenches, the protective layer comprising a plurality of openings that expose the LEDs;
a first conductive layer, wherein the first conductive layer covers the protective layer and is connected to another end of the LEDs through the openings, and a portion of the first conductive layer covers an area of the trenches, a material of the first conductive layer being a transparent conductive material; and
a second conductive layer, wherein the second conductive layer is directly disposed on one side of the first conductive layer away from the base substrate, and the second conductive layer at least covers the area of the trenches.

12. The light-emitting diode (LED) panel according to claim 11, wherein the first conductive layer includes a first portion and a second portion connected to the first portion; the first portion is disposed in an area of the LEDs, and the second portion is disposed in the area of the trenches; a thickness of the first portion is greater than a thickness of the second portion;
in the area of the trenches, a combined thickness of the second portion and the second conductive layer is greater than or equal to the thickness of the first portion.

13. The light-emitting diode (LED) panel according to claim 12, wherein the trenches comprise a first trench and a second trench connected to each other; the first trench extends through the LED epitaxial layer, and the second trench extends through the second conductive bonding layer and the first conductive bonding layer;
a width of an opening end of the first trench is greater than a width of an opening end of the second trench; a thickness of a portion of the first conductive layer located at the first trench is greater than a thickness of a portion of the first conductive layer located at the second trench; a thickness of a portion of the second conductive layer located at the first trench is greater than a thickness of a portion of the second conductive layer located at the second trench;
a combined thickness of the portion of the first conductive layer and the portion of the second conductive layer located at the second trench is greater than or equal to the thickness of the first portion.

14. The light-emitting diode (LED) panel according to claim 13, wherein the second conductive layer comprises a covering portion and a filling portion connected to the covering portion; the covering portion covers an area of the second portion corresponding to the first trench, and the filling portion fills a recess of the second portion corresponding to the second trench.

15. The light-emitting diode (LED) panel according to claim 13, wherein the second conductive layer covers a surface of the second portion away from the base substrate.

16. The light-emitting diode (LED) panel according to claim 13, further comprising a third conductive layer, wherein the third conductive layer is disposed between the LEDs and the second conductive bonding layer, and the second trench extends through the third conductive layer.

17. The light-emitting diode (LED) panel according to claim 11, wherein a width of an opening end of each of the trenches is less than 0.6 micrometers.

18. The light-emitting diode (LED) panel according to claim 11 wherein the second conductive layer is a single-layer structure.

19. The light-emitting diode (LED) panel according to claim 11 wherein the second conductive layer is a multi-layer stack structure.

20. The light-emitting diode (LED) panel according to claim 19, wherein the second conductive layer comprises an electroplating seed layer and an electroplated metal layer disposed on the electroplating seed layer, with the electroplating seed layer covering the first conductive layer.
